(19) United States
(12) Patent Application Publication
(10) Pub. No.: US 2026/0059750 A1
(43) Pub. Date: Feb. 26, 2026

(54) SEMICONDUCTOR DEVICE AND FABRICATION METHODS THEREOF

(71) Applicant: Yangtze Memory Technologies Co., Ltd., Wuhan (CN)

(72) Inventors: Yuhuan ZHENG, Wuhan (CN); Yonggang YANG, Wuhan (CN); Wenxi ZHOU, Wuhan (CN)

(21) Appl. No.: 18/904,025

(22) Filed: Oct. 1, 2024

Related U.S. Application Data
(63) Continuation of application No. PCT/CN2024/114459, filed on Aug. 26, 2024.

(51) Int. Cl. H10B 43/27; H10B 41/10; H10B 41/27; H10B 41/35; H10B 43/10; H10B 43/35

(52) U.S. Cl. CPC H10B 43/27; H10B 41/10; H10B 41/27; H10B 41/35; H10B 43/10; H10B 43/35

(57) ABSTRACT

Methods, devices, systems, and techniques for managing contact structures in semiconductor devices are provided. In one aspect, a semiconductor device includes a first stack of conductive layers and isolating layers alternating with each other along a first direction. The first stack includes: one or more first conductive layers and one or more first isolating layers that alternate with each other, and second conductive layers and second isolating layers that alternate with each other. The one or more first conductive layers and the one or more first isolating layers are stacked with the second conductive layers and second isolating layers along the first direction. The semiconductor device further includes at least one connection structure extending through at least one of the one or more first conductive layers along the first direction and being connected with the at least one of the one or more first conductive layers.

### CROSS-REFERENCE TO RELATED APPLICATIONS

This application is a continuation of International Application No. PCT/CN2024/114459, filed on Aug. 26, 2024, the disclosure of which is hereby incorporated by reference in its entirety.

### TECHNICAL FIELD

The present disclosure relates to semiconductor devices and fabrication methods thereof.

### BACKGROUND

Semiconductor devices, e.g., memory devices, can have various structures to increase a density of memory cells and lines on a chip. For example, three-dimensional (3D) memory devices are attractive due to their capability to increase an array density by stacking more layers within a similar footprint. A 3D memory device normally includes a memory array of memory cells and peripheral circuits for facilitating operations of the memory array.

### SUMMARY

The present disclosure describes methods, devices, systems, and techniques for managing contact structures in semiconductor devices.

One aspect of the present disclosure features a semiconductor device. The semiconductor device includes a first stack of conductive layers and isolating layers alternating with each other along a first direction, where the first stack includes one or more first conductive layers and one or more first isolating layers that alternate with each other, and second conductive layers and second isolating layers that alternate with each other, where the one or more first conductive layers and the one or more first isolating layers are stacked with the second conductive layers and second isolating layers along the first direction. The semiconductor device further includes at least one connection structure extending through at least one of the one or more first conductive layers along the first direction and being connected with the at least one of the one or more first conductive layers.

In some implementations, the at least one connection structure extends through the one or more first conductive layers and the one or more first isolating layers along the first direction and is connected to the one or more first conductive layers.

In some implementations, the semiconductor device further includes two adjacent gate line isolation structures each extending through the first stack along the first direction, where the two adjacent gate line isolation structures being spaced from each other along a second direction perpendicular to the first direction and defining at least one block structure, and channel structures between the two adjacent gate line isolation structures, each of the channel structures extending through the first stack along the first direction.

In some implementations, the semiconductor device further includes one or more isolation structures between the two adjacent gate line isolation structures along the second direction, where the one or more isolation structures separate the block structure into two or more sub-block structures, and where the at least one connection structure comprises a connection structure in a corresponding sub-block structure.

In some implementations, the connection structure is between one of the two adjacent gate line isolation structures and one of the one or more isolation structures adjacent to the one of the two adjacent gate line isolation structures along the second direction, or the connection structure is between two adjacent isolation structures of the one or more isolation structures along the second direction.

In some implementations, a number of the at least one connection structure is greater than a number of the one or more isolation structures.

In some implementations, the one or more isolation structures include an isolation structure extending through the one or more first conductive layers and the one or more first isolating layers along the first direction, where the isolation structure is in contact with one of the second isolating layers.

In some implementation, along the first direction, a length of the connection structure is no greater than a length of the isolation structure.

In some implementation, the channel structures include a first channel structure that is partially surrounded by the isolation structure, and where the isolation structure is in contact with an outer layer of the first channel structure.

In some implementation, the channel structures include a second channel structure that is partially surrounded by the connection structure, where the connection structure is in contact with an outer layer of the second channel structure.

In some implementation, the connection structure includes a conductive material, where the conductive material is in contact with the one or more first conductive layers along the first direction.

In some implementations, the connection structure is continuous or intermittent along a third direction perpendicular to the first direction and the second direction.

In some implementation, the connection structure in the corresponding sub-block structure is coupled to an interconnect structure through at least one coupling-out structure.

In some implementations, the semiconductor device further includes gate line structures each extending through the first stack along the first direction, two adjacent gate line slits being spaced from each other along the second direction perpendicular to the first direction and defining a block, one or more gate line isolation structures between the two adjacent gate line slits, the one or more gate line isolation structures separating the block into two or more block structures, and one or more isolation structures between two adjacent gate line isolation structures or between a gate line structure and an adjacent gate line isolation structure, the one or more isolation structure separating a block structure into two or more sub-block structures.

In some implementations, the semiconductor device further includes a second stack of dielectric layers and isolating layers alternating with each other along the first direction, where the second stack is adjacent to the first stack along the second direction perpendicular to the first direction, and contact structures extending through the second stack along the first direction, where one of the second conductive layers of the first stack is connected to a corresponding contact structure of the contact structures.

Another aspect of the present disclosure features a method of forming a semiconductor device. The method includes forming a first stack comprising one or more first conductive layers and one or more first isolating layers that alternate with each other along a first direction, and second conductive layers and second isolating layers that alternate with each other along the first direction, where the one or more first conductive layers and the one or more first isolating layers are stacked with the second conductive layers and second isolating layers along the first direction, The method further includes forming one or more connection structures, where the one or more connection structures extend through at least one of the one or more first conductive layers along the first direction and is connected with the at least one of the one or more first conductive layers.

In some implementations, where the forming of the first stack includes: forming a stack of dielectric layers and isolating layers alternating with each other along the first direction, etching one or more first dielectric layers and one or more first isolating layers in the stack along the first direction and a second direction in a first region to form one or more first spaces, the second direction being perpendicular to the first direction, and filling a first dielectric material into the one or more first spaces to form one or more isolation structures in the first region.

In some implementations, the first dielectric material is different from a dielectric material of the dielectric layers.

In some implementations, the method includes: etching one or more first dielectric layers and one or more first isolating layers along the first direction in the first region to form one or more second spaces, where the one or more second spaces and the one or more first spaces are at different positions along a third direction perpendicular to the first direction, and filling a second dielectric material into the one or more second spaces to form one or more second filled spaces, the second dielectric material being different from the first dielectric material.

In some implementations, the one or more second filled spaces are in continuous or intermittent contact with the one or more first dielectric layers along a third direction perpendicular to the first direction and the second direction.

In some implementations, a length of the one or more second filled spaces along the first direction are no greater than a length of the one or more isolation structures along the first direction.

In some implementations, the forming of the first stack further includes: forming channel structures in the first region, where the channel structures comprise a first channel structure, second channel structure and a third channel structure.

In some implementations, forming the channel structures is after the forming of the one or more isolation structures and the forming of the one or more second filled spaces.

In some implementations, the forming of the first channel structure including: etching through the stack of dielectric layers and isolating layers and a portion of the one or more isolation structures to form first holes, and filling one or more filling materials into the first holes to from the first channel structure, where the first channel structure partially surrounded by the corresponding isolation structure that is in contact with an outer layer of the first channel structure.

In some implementations, the forming of the second channel structure including: etching through the stack of dielectric layers and isolating layers and a portion of the one or more second filled spaces to form second holes, where the second holes and the first holes are separated from each other along the second direction, and filling one or more filling materials into the second holes to from the second channel structure, where the second channel structure partially surrounded by the corresponding second filled spaces that is in contact with an outer layer of the first channel structure.

In some implementations, the forming of the third channel structure including: etching through the stack of dielectric layers and isolating layers to form third holes, where the third holes, the second holes, and the first holes are separated from each other along the second direction and filling one or more filling materials into the second holes to from the third channel structure.

In some implementations, the forming of the one or more connection structures includes: etching through the stack of dielectric layers and isolating layers along the first direction in the first region to form third spaces, where the one or more second filled spaces and the one or more first spaces are between two adjacent third spaces along the third direction. The method further includes: removing the dielectric layers of the stack and the one or more second filled spaces via the third spaces to form a fourth space, filling a conductive material into the fourth space to form the conductive layers of the first stack and the one or more connection structures, and forming gate line isolation structures in the third spaces.

Another aspect of the present disclosure features a semiconductor device. The semiconductor device includes a first stack comprising conductive layers and isolating layers alternating with each other along a first direction, channel structures extending through the first stack, and at least one connection structure extending through at least one conductive layer and at least one isolating layer of the first stack along the first direction and being connected with the at least one conductive layer, where the at least one conductive layer and the at least one isolating layer locate at a side of the first stack along the first direction.

In some implementations, the semiconductor device further including: gate line isolation structures each extending through the first stack along the first direction, the gate line isolation structures being spaced from each other along a second direction perpendicular to the first direction and defining at least one block structure, and one or more isolation structures between two adjacent gate line isolation structures along the second direction, where the one or more isolation structures separate one block structure into two or more sub-block structures, and where the at least one connection structure comprises a connection structure in a corresponding sub-block structure.

In some implementations, the connection structure is between one of the two adjacent gate line isolation structures and one of the one or more isolation structures adjacent to the one of the two adjacent gate line isolation structures along the second direction, or the connection structure is between two adjacent isolation structures of the one or more isolation structures along the second direction.

In some implementations, the connection structure in the corresponding sub-block structure is coupled to an interconnect structure through at least one coupling-out structure.

A further aspect of the present disclosure features a memory system. The memory system includes a memory device and a memory controller coupled to the memory device and configured to control the memory device. The memory device includes a stack of conductive layers and isolating layers alternating with each other along a first direction, where the stack includes: one or more first conductive layers and one or more first isolating layers that alternate with each other, and second conductive layers and second isolating layers that alternate with each other, where the second conductive layers and second isolating layers is stacked with the first conductive layers and first isolating layers along the first direction, and at least one connection structure extending through at least one of the one or more first conductive layers of the stack along the first direction and being connected with the at least one of the one or more first conductive layers.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF DRAWINGS

FIG. 1 illustrates a top view of an example semiconductor device.

FIG. 2A illustrates another top view of an example semiconductor device.

FIG. 2B illustrates a cross-section view of an example semiconductor device.

FIGS. 3A-3K illustrate an example process of manufacturing a semiconductor device.

FIG. 4 illustrates a flow chart of an example process of manufacturing a semiconductor device.

FIG. 5 illustrates a block diagram of an example system.

Like reference numbers and designations in the various drawings indicate like elements. It is also to be understood that the various exemplary implementations shown in the figures are merely illustrative representations and are not necessarily drawn to scale.

### DETAILED DESCRIPTION

Due to a demand for cheaper memory devices with a higher density, a memory device (e.g., a 3D NAND flash memory) can be formed to have a large number of layers and a high aspect ratio. The large number of layers and the high aspect ratio of such memory devices may bring challenges to the manufacturing process. For example, the large number of layers may increase the difficulty of etching conductive materials through the conductive layers when forming the connection structure. In another example, the high aspect ratio between a conductive layer and an isolating layer may pose challenges in removing the sacrificial material when filling the conductive layers with conductive materials. In another example, a higher density memory device can lead to a complex device structure, which increases the fabrication cost. Therefore, connection structures and fabrication methods that can solve the aforementioned issues are desirable.

In one or more implementations of the present disclosure, an example semiconductor device is provided. The semiconductor device includes a first stack of alternating conductive layers and isolating layers, where the first stack includes one or more first conductive layers and one or more first isolating layers that alternate with each other, and second conductive layers and second isolating layers that alternate with each other. The one or more first conductive layers and the one or more first isolating layers are stacked with the second conductive layers and second isolating layers along a vertical direction. The semiconductor device further includes at least one connection structure extending through at least one of the one or more first conductive layers along the first direction and being connected with the at least one of the one or more first conductive layers.

Implementations of the present disclosure can provide one or more of the following technical advantages and/or benefits. For example, in the example semiconductor device described above, the connection structure space can be etched and filled with a sacrificial material before the formation of the conductive layers. The etching process only etches though dielectric layers and isolation layers that include dielectric materials. Thus, the techniques described in the present disclosure allow for precise control of the etching depth along an etching direction. Also, the sacrificial material in the connection structure space is same as a sacrificial material in the dielectric layers before filling of a conductive material. Both sacrificial materials can be removed and replaced with a conductive material simultaneously to assist in the removal of the sacrificial material. The techniques also can make it easier to manufacture reliable connection structures in the first stack of the semiconductor device, thereby reducing the fabrication cost and increasing the production yield.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

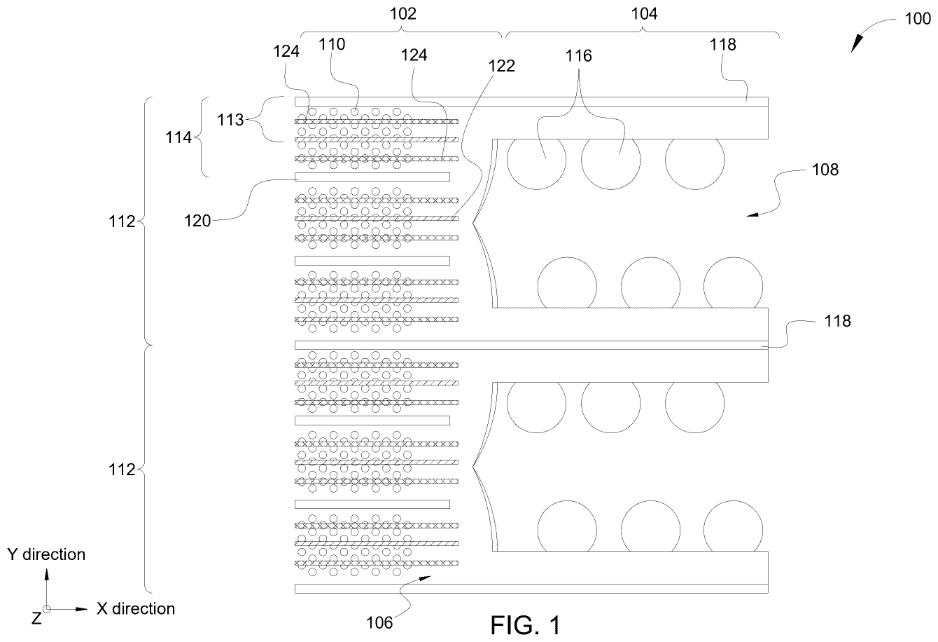

It is noted that X, Y, and Z axes (also referred to as X, Y, and Z directions) are included in FIG. 1 to further illustrate the spatial relationship of various components in a semiconductor device. A substrate of the semiconductor device can include two lateral surfaces extending laterally in the X-Y plane: a top surface on the front side of the substrate on which a component of the semiconductor device can be formed, and a bottom surface on the backside opposite to the front side of the substrate. The Z direction is perpendicular to both the X and Y directions. As used in the present disclosure, whether one component (e.g., a layer or a device) is “on,” “above,” or “below” another component (e.g., a layer or a device) of the semiconductor device is determined relative to the substrate of the semiconductor device in the Z direction (the vertical direction perpendicular to the X-Y plane, e.g., the thickness direction of the substrate) when the substrate is positioned in the lowest plane of the semiconductor device in the Z direction. The same notion for describing the spatial relationships is applied throughout the present disclosure.

FIG. 1 illustrates a top view of an example semiconductor device 100. In some implementations, the semiconductor device 100 can be a memory device, such as a three-dimensional (3D) NAND memory device. The semiconductor device 100 can include one or more array regions and one or more connection regions configured to provide conductive connections for the one or more array regions. In some implementations, as shown in FIG. 1, the semiconductor device 100 includes an array region 102 and a connection region 104 adjacent to the array region 102 along a first horizontal direction (e.g., the X direction). It is understood that the example in FIG. 1 is for illustration purpose and is not intended to be construed in a limiting sense. In practice, any suitable arrangement of various regions in the semiconductor device 100 can be applied. In some implementations, the semiconductor device 100 can have two connection regions 104 and an array region 102 arranged between the two connection regions 104 along the X direction. In some implementations, the semiconductor device 100 can have two array regions 102 and a connection region 104 between the two array regions 102 along the X direction.

The semiconductor device 100 includes a stack 106 of alternating conductive layers and isolating layers. In some implementations, a part of the stack 106 can be in the array region 102, and another part of the stack 106 can be in the connection region 104. The semiconductor device 100 further includes a stack 108 of alternating dielectric layers and isolating layers. In some implementations, the stack 108 can be in the connection region 104. The stack 106 is connected to the stack 108.

The semiconductor device 100 can include an array of channel structures 110 extending through the stack 106 in the array region 102. Each channel structure 110 can be used to form a string of memory cells coupled in serial along a vertical direction (e.g., Z direction) perpendicular to the first horizontal direction.

The semiconductor device 100 can include contact structures 116 in the connection region 104. A contact structure 116 can be configured to connect a corresponding one of the conductive layers of the stack 106 to a peripheral circuit.

The semiconductor device 100 can include one or more gate line structures 118. Each gate line structure 118 can extend in the X direction. The gate line structures 118 are spaced from each other along the Y direction. The gate line structures 118 can extend into both the array region 102 and the connection region 104. In some implementations, as shown in FIG. 1, the gate line structures 118 can divide an array region 102 into multiple blocks 112. In some implementations, the gate line structure 118 can function as a common source contact for the channel structures 110 in the array region 102. In some implementations, the semiconductor device 100 can also include one or more gate line isolation structures 120 in between two gate line structures 118. The gate line isolation structures 120 extend along the X direction. The gate line isolation structures 120 are spaced from each other along the Y direction. In some implementations, as shown in FIG. 1, the gate line isolation structures 120 can divide the blocks 112 in to two or more block structures 114.

As shown in FIG. 1, each block structure 114 can be separated by one or more isolation structures 122. The isolation structures 122 extend along the X direction and divide a block structure 114 in to two or more sub-block structure 113. In some implementations, the isolation structures 122 can eliminate or reduce stress built in the gate line structures 118 during the manufacturing process, thereby preventing the gate line structures 118 from bending or cracking. In some implementations, as shown in FIG. 1, the channel structures 110 can be partially surrounded by the isolation structure 122 along the Y direction, where the channel structures 110 extend through the stack 106 and a portion of the isolation structure 122 along a third direction (e.g., Z direction).

In some implementations, as shown in FIG. 1, the semiconductor device 100 can include one or more connection structures 124. As shown in FIG. 1, the connection structure 124 is between one of the two adjacent gate line isolation structures 120 and one of the one or more isolation structures 122 adjacent to the one of the two adjacent gate line isolation structures 120 along the Y direction. In some implementations (not shown in FIG. 1), the connection structures 124 is between two adjacent isolation structures 122. In some implementations, (not shown in FIG. 1), the connection structures 124 is between one of the two adjacent gate line structures 118 and one of the one or more isolation structures 122 adjacent to the one of the two adjacent gate line structures 118. In some implementations, as shown in FIG. 1, the connection structures 124 is continuous along the X direction. In some implementations, the connection structures 124 is intermittent along the X direction (not shown in FIG. 1). In some implementations, as shown in FIG. 1, the channel structures 110 can be partially surrounded by the connection structure 124 along the Y direction, where the channel structures 110 extend through the stack 106 and a portion of the connection structure 124 along the Z direction.

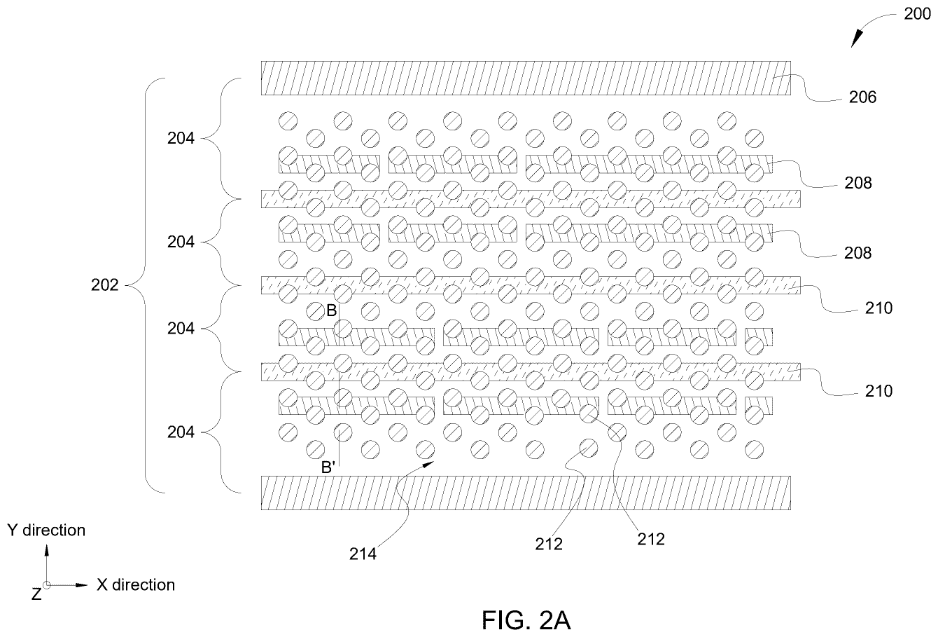

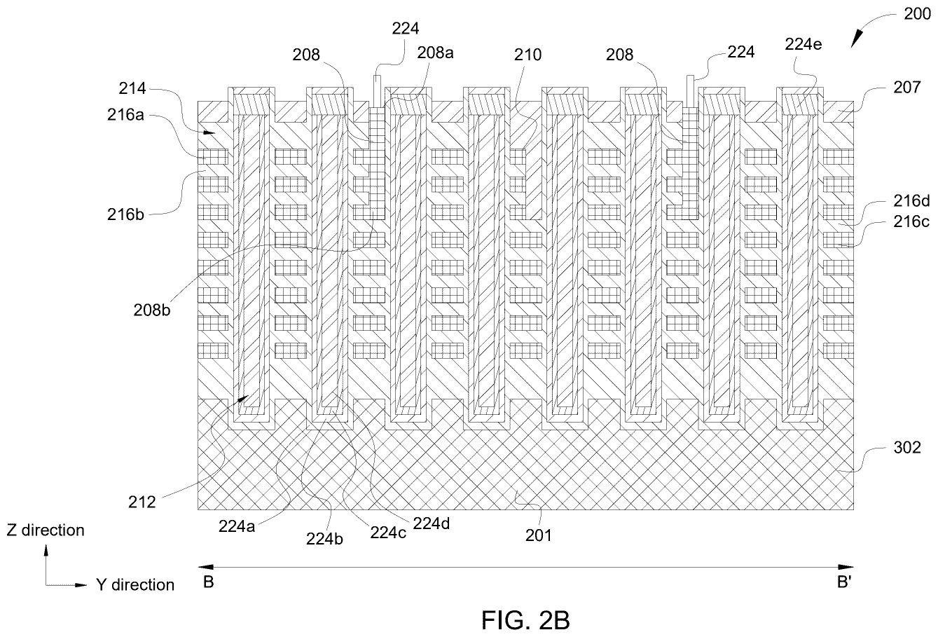

FIGS. 2A-2B illustrate example semiconductor devices. FIG. 2A illustrates a top view of an example semiconductor device 200. In some implementation, the semiconductor device 200 can be similar to, or same as the block 112 of the semiconductor device 100 as shown in FIG. 1. In some implementations, the semiconductor device 200 can be similar to, or same as the block structure 114 of the semiconductor device 100 of FIG. 1. The semiconductor device 200 includes a stack 214 of alternating conductive layers and isolating layers (e.g., one or more first conductive layers 216a, one or more first isolating layers 216b, second conductive layers 216c, and second isolating layers 216d in FIG. 2B). In some implementations the stack 214 can be similar to, or same as, the stack 106 in the array region 102 of the semiconductor device 100 as shown in FIG. 1.

The semiconductor device 200 can include an array of channel structures 212 extending through the stack 214. In some implementations the channel structures 212 can be similar to, or same as, the channel structures 110 as shown in FIG. 1, of the semiconductor device 100. The semiconductor device 200 can include one or more gate line isolation structures 206. The gate line isolation structures 206 extend along the X direction. In some implementations, as shown in FIG. 2A, two adjacent gate line isolation structures are spaced from each other along the Y direction defining a block structure 202. In some implementations, the gate line isolation structures can be similar, or as same as, the gate line isolation structures 120 of the semiconductor device 100. In some implementations, one of the two adjacent gate line isolation structures 206 can be similar to, or same as, the gate line structure 118 of the semiconductor device 100 as shown in FIG. 1. In some implementations (not shown in FIGS. 2A-2B), the number of the gate line isolation structures 206 can be greater than two, where the gate line isolation structures 206 separate the stack 214 into multiple block structures 202.

As shown in FIG. 2A, each block structure 202 can be separated by one or more isolation structures 210. The isolation structures 210 extend along the X direction and divide a block structure 202 in to two or more sub-block structures 204. In some implementations, as shown in FIG. 2A, the channel structures 212 can be partially surrounded by the isolation structure 210 along the Y direction, where the channel structures 212 extend through the stack 214 and a portion of the isolation structure 210 along the Z direction. In some implementations, the isolation structure 210 can be similar to, or same as, the isolation structure 122 of the semiconductor device 100 as shown in FIG. 1.

In some implementations, as shown in FIG. 2A, the semiconductor device 200 includes at least one connection structure 208 in each of the sub-block structures 204. As shown in FIG. 2A, the connection structure 208 is between one of the two adjacent gate line isolation structures 206 and one of the one or more isolation structures 210 adjacent to the one of the two adjacent gate line isolation structures 206 along the Y direction. In some implementations, as shown in FIG. 2A, the connection structures 208 is between two adjacent isolation structures 210. In some implementations, as shown in FIG. 2A, the connection structure 208 is intermittent along the X direction. In some implementations (not shown in FIG. 2A), the connection structure 208 is continuous along the X direction. In some implementations, as shown in FIG. 2A, the channel structures 212 can be partially surrounded by the connection structure 208 along the Y direction, where the channel structures 212 extend through the stack 214 and a portion of the connection structure 208 along the Z direction. In some implementations (not shown in FIGS. 2A-2B), a number of the connection structures within each sub-block structures 204 can be greater than 1. In some implementations, a number of the connection structures 208 is greater than a number of the one or more isolation structures 210. In some implementations, the connection structure 208 can be similar to, or same as, the connection structure 124 of the semiconductor device 100 as shown in FIG. 1.

FIG. 2B illustrates a cross-sectional view of the semiconductor device 200 along cut line BB′ of FIG. 2A. The stack 214 of conductive layers and isolating layers alternate with each other along the Z direction. As shown in FIG. 2B, the stack 214 can include one or more first conductive layers 216a and one or more first isolating layers 216b that alternate with each other, and second conductive layers 216c and second isolating layers 216d that alternate with each other. In some implementations, as shown in FIG. 2B, the one or more first conductive layers 216a and the one or more first isolating layers 216b are stacked with the second conductive layers 216c and isolating layers 216d along the Z direction. In some implementations (not shown in FIG. 2B), the stack 214 can include conductive layers and isolating layers alternating with each other along the Z direction.

The stack 214 can extend in the Y direction that is parallel to a top surface of the semiconductor device 200 and perpendicular to the X direction. The one or more first conductive layers 216a and the one or more first isolating layers 216b can alternate in the Z direction perpendicular to the X and Y direction. The second conductive layers 216c and the second isolating layers 216d can alternate in the Z direction. The one or more first conductive layers 216a and the second conductive layers 216c can be the same or different from each other in thickness, for example, ranging from 10-500 nm, e.g., about 35 nm. The one or more first isolating layers 216b and the second isolating layers 216d can also be the same or different from each other in thickness, for example, ranging from 10-500 nm, e.g., about 25 nm. It should be noted that the number of the one or more first conductive layers 216a, the one or more first isolating layers 216b, the second conductive layers 216c, and the second isolating layers 216d shown in FIG. 2B is for illustration only and that any suitable number of the one or more first conductive layers 216a, the one or more first isolating layers 216b, the second conductive layers 216c, and the second isolating layers 216d can be included in the stack 214. The first conductive layers 216a and the second conductive layers 216c can include any suitable conducting material, such as tungsten (W), cobalt (Co), copper (Cu), aluminum (Al), titanium nitride (TiN), polycrystalline silicon (polysilicon), doped silicon, silicides, or any combination thereof. The one or more first isolating layers 216b and the second isolating layers 216d can include a dielectric material, such as silicon oxide, silicon nitride, silicon oxynitride, or any combination thereof. In some implementations, the first isolating layers 216b and the second isolating layers 216d can also include high-K dielectric materials, such as hafnium oxide, zirconium oxide, aluminum oxide, tantalum oxide, lanthanum oxide, or any combination thereof.

The semiconductor device 200 includes an array of channel structures 212. Each channel structure 212 can extend through the stack 214 along the Z direction. In some examples, the channel structure 212 can be in the shape of a cylinder or a pillar, and can include an outer layer 224a, a block layer surrounded by the outer layer, a charge trapping layer (or a storage layer) surrounded by the block layer, a tunneling layer surrounded by the charge trapping layer, a channel layer 224c surrounded by the tunneling layer, and a core filler layer 224d surrounded by the channel layer 224c, and a channel plug 224e formed above the core filler layer 224d and being in contact with the channel layer 224c. In some implementations, the channel layer 224c can include silicon, such as amorphous silicon, polysilicon, or single crystalline silicon, the tunneling layer can include silicon oxide, silicon nitride, or any combination thereof, the blocking layer can include silicon oxide, silicon nitride, high-K dielectrics, or any combination thereof, and the charge trapping layer can include silicon nitride, silicon oxynitride, silicon, or any combination thereof. In some implementations, the tunneling layer, the charge trapping layer, and the blocking layer, collectively referred to as a memory film 224b, can include ONO dielectrics (silicon Oxide-silicon Nitride-silicon Oxide). Each channel structure 212 can be similar to, or same as, the channel structure 110 of the semiconductor device 100 as shown in FIG. 1.

The semiconductor device 200 can include one or more isolation structures 210. In some implementations, as shown in FIG. 2B, the one or more isolation structures 210 extend through the one or more first conductive layers 216a and the one or more first isolating layers 216b along the Z direction. In some implementations, as shown in FIG. 2B, the one or more isolation structures 210 are in contact with an isolating layer of the second isolating layers 216d. In some implementations, the isolating layer of the second isolating layers 216d is connected to the first conductive layers 216a. In some implementations, the isolating layer of the second isolating layers 216d is connected to the first isolating layers 216b. The one or more isolation structures 210 can include a dielectric material, such as silicon oxide, silicon nitride, silicon oxynitride, or any combination thereof. In some implementations, the dielectric material of the one or more isolation structures 210 may be same with that of the one or more first isolating layers 216b.

As shown in FIG. 2B, the semiconductor device 200 can include at least one connection structure 208 between two adjacent isolation structures 210. The connection structure 208 extends through and connects with the at least one of the one or more first conductive layers 216a along the Z direction. In some implementations, as shown in FIG. 2B, the connection structure 208 extends through the one or more first conductive layers 216a and the one or more first isolation layers 216b along the Z direction. In some implementations, as shown in FIG. 2B, a length of the connection structure 208 is equal to a length of the one or more isolation structures 210 along the Z direction. In some implementations (not shown in FIG. 2B), the length of the connection structure 208 is smaller than the length of the one or more isolation structure 210 along the Z direction. In some implementations, a number of the first conductive layers 216a that is extended through by the isolation structures 210 may be same with a number of the first conductive layers 216a that is extended through by the connection structures 208. The connection structure 208 can include any suitable conducting material, such as tungsten (W), cobalt (Co), copper (Cu), aluminum (Al), titanium nitride (TiN), polycrystalline silicon (polysilicon), doped silicon, silicides, or any combination thereof. In some implementation, the conducting material of the connection structure can be similar to, or same as, the conducting material of the first conductive layers 216a and the second conductive layers 216c.

The connection structure 208 has an end 208a and an end 208b opposite to one another along the Z direction. The end 208a is closer to the top layer 207 than the end 208b along the Z direction. The end 208a can be exposed from the top layer 207 and can be configured to be coupled out to an interconnect structure through a coupling-out structure 224, as shown in FIG. 2B. The end 208b is connected to one of the one or more first conductive layer 216a. In some implementations, the coupling-out structure 224 can be a via structure that extends through the top layer 207 and is connected to the connection structure 208.

In some implementation (not shown in FIGS. 2A-2B), the semiconductor device 200 can include a second stack of dielectric layers and isolating layers alternating with each other along the Z direction, where the second stack is adjacent to the stack 214 along X direction. The semiconductor device 200 can further include contact structures extending through the second stack along the Z direction, where one of the second conductive layers 216c of the stack 214 is connected to a corresponding contact structure of the contact structures. In some implementations, the second stack can be similar to, or same as, the stack 108 of the connection region 104 of the semiconductor device 100 as shown in FIG. 1. In some implementations, the contact structures of the second stack can be similar to, or same as, the contact structures 116 of the semiconductor device 100 as shown in FIG. 1.

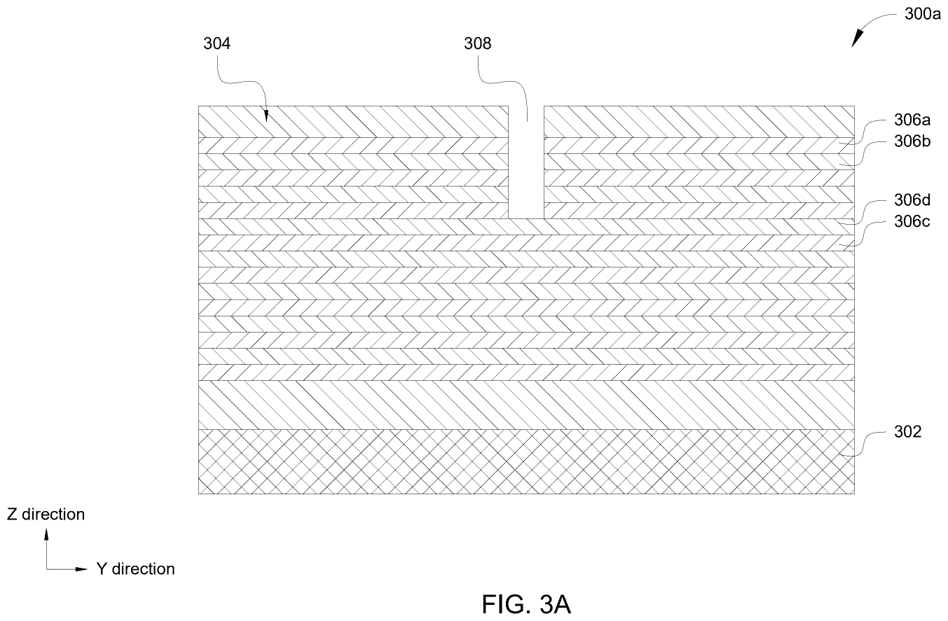

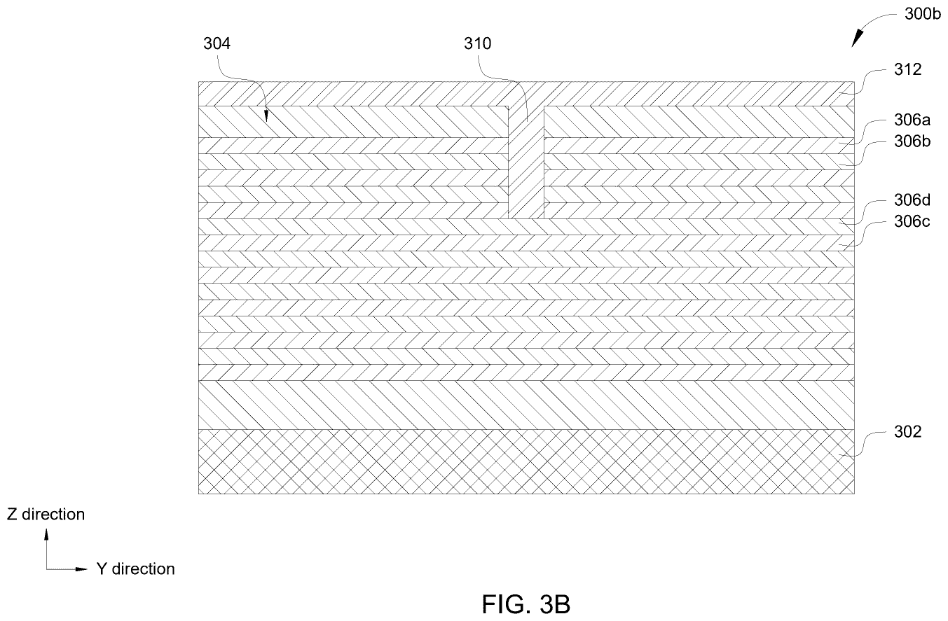

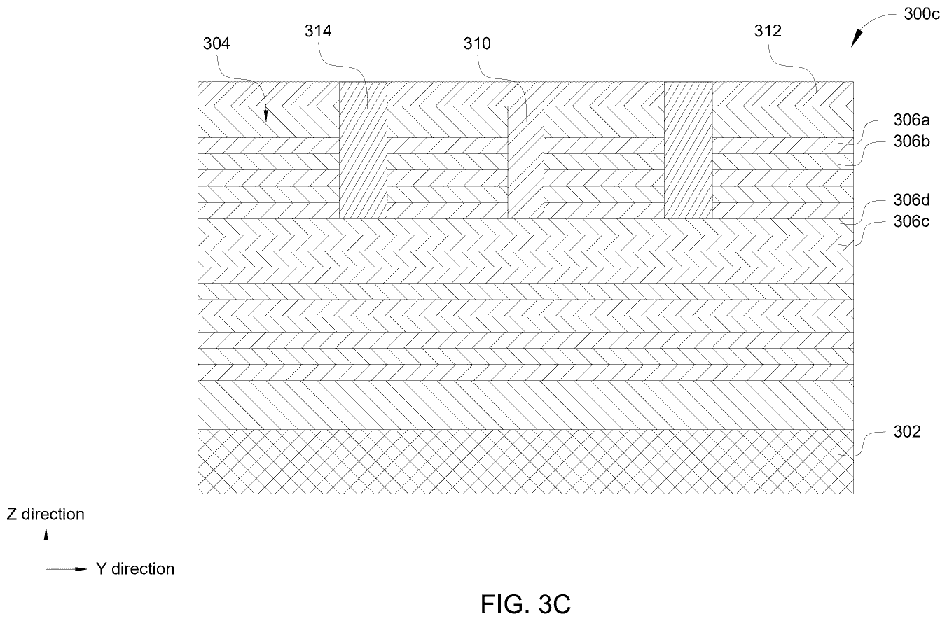

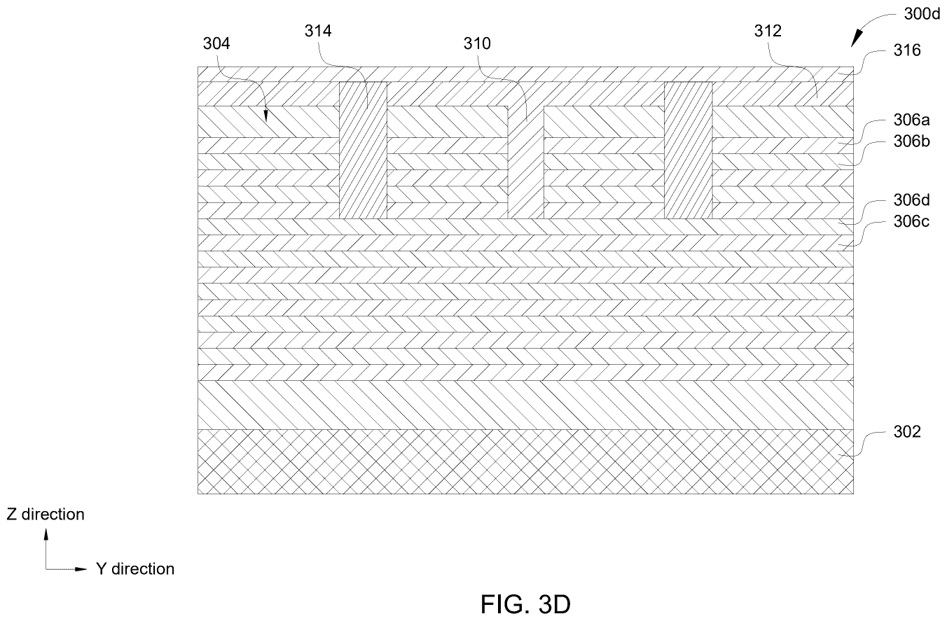

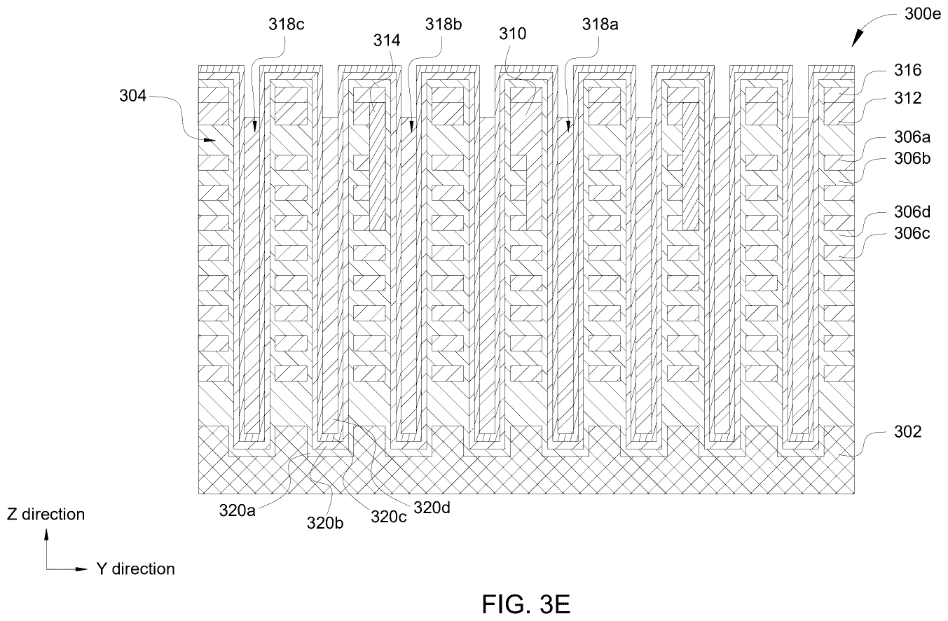

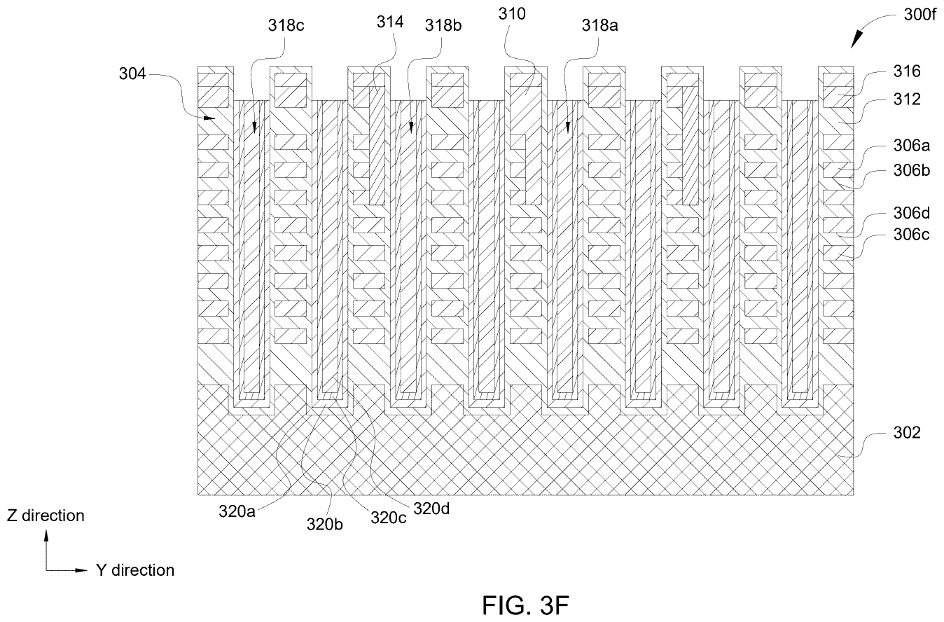

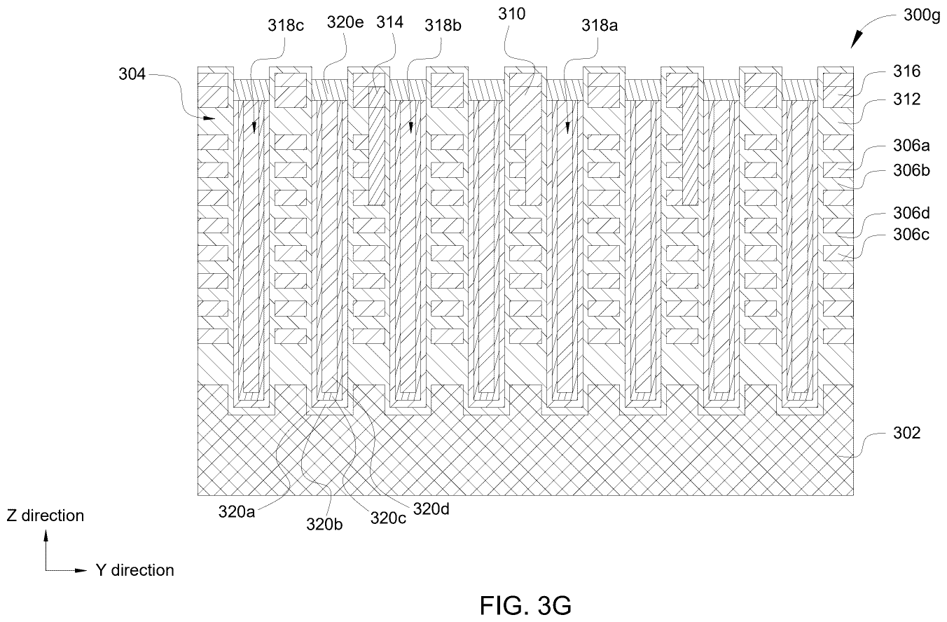

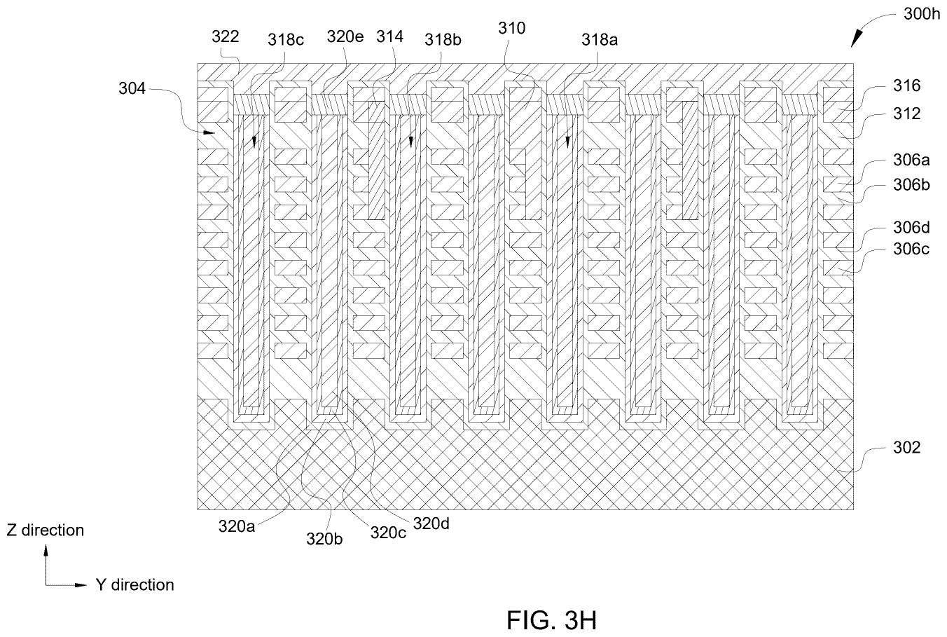

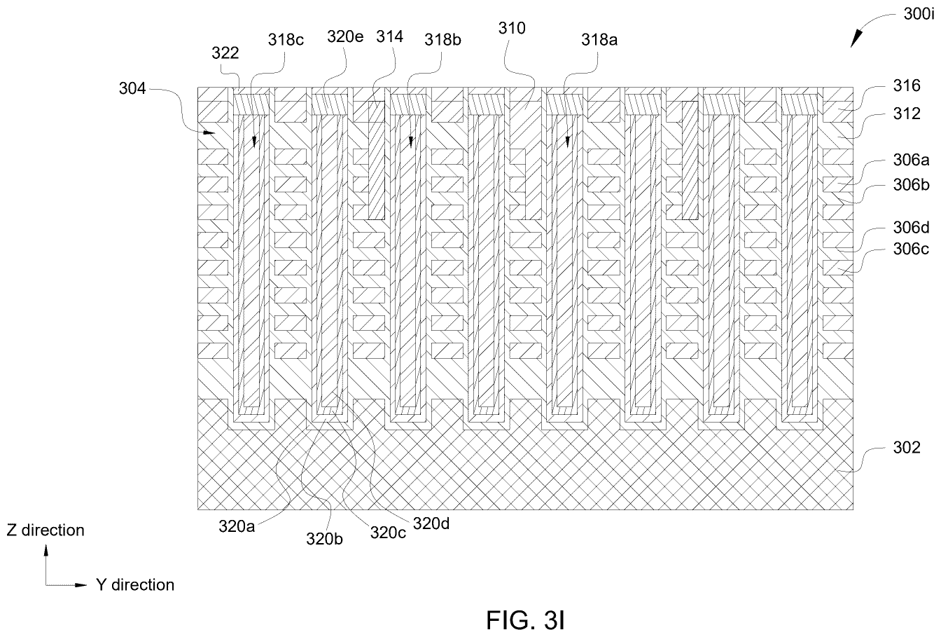

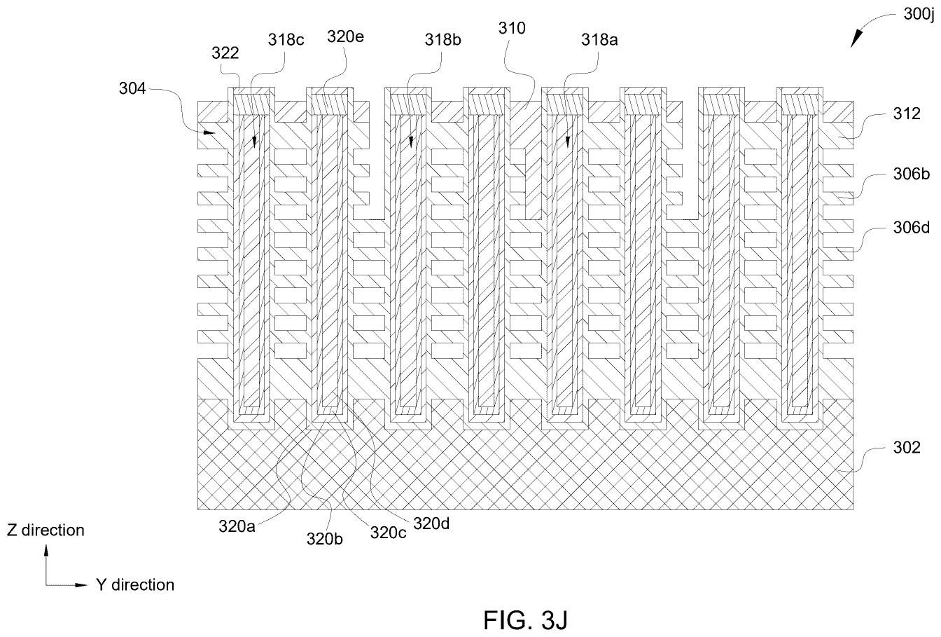

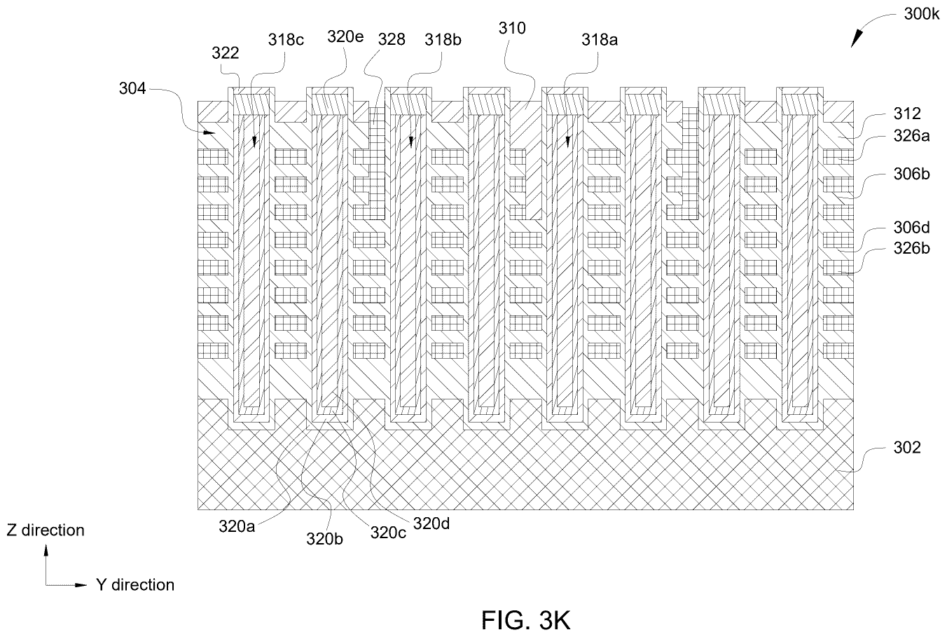

FIGS. 3A-3K illustrate an example process of fabricating a semiconductor device, such as the semiconductor device 200 as illustrated in FIGS. 2A-2B. FIGS. 3A-3K show cross-sectional views of example semiconductor structures at various stages of the fabrication process. Specifically, FIGS. 3A-3K illustrate cross-sectional views of example semiconductor structures along the cut line BB′ of FIGS. 2A-2B.

As shown in FIG. 3A, a semiconductor structure 300a is formed. The semiconductor structure 300a includes a substrate 302 and a stack 304 of one or more first dielectric layers 306a and one or more first isolating layers 306b that alternate with each other along a vertical direction (e.g., Z direction). The stack 304 further includes second dielectric layers 306c and second isolating layers 306d that alternate with each other along the Z direction, where the one or more first dielectric layers 306a and the one or more first isolating layers 306b are stacked with the second dielectric layers 306c and the second isolating layers 306d along the Z direction. Each first dielectric layer 306a and second dielectric layer 306c can also be referred to as a sacrificial layer. The substrate 302 and each of the first dielectric layers 306a, first isolating layers 306b, second dielectric layers 306c, and second isolating layers 306d can extend in the X-Y plane. The semiconductor structure 300a can be formed by, for example, depositing the first dielectric layers 306a, first isolating layers 306b, second dielectric layers 306c, and second isolating layers 306d on top of the substrate 302. The semiconductor structure 300a can include one or more first spaces 308. The one or more first spaces 308 can be formed by etching the one or more first dielectric layers 306a and the one or more first isolating layers 306b in the stack 304 along the Z direction and a horizontal direction (e.g., the Y direction) perpendicular to the Z direction. The one or more first spaces 308 extend through the one or more first dielectric layers 306a and the one or more first isolating layers 306b and are connected to an isolating layer of the second isolating layers 306d, where the isolating layer of the second isolating layers 306d is connected with the one or more first dielectric layers 306a. The one or more first isolating layers 306b and the second isolating layers 306d can include dielectric material, such as silicon oxide, silicon nitride, silicon oxynitride, or any combination thereof. In some implementations, the one or more first dielectric layers 306a and the second dielectric layers 306c can include a dielectric material different from the dielectric material of the one or more first isolating layers 306b and the second isolating layers 306d. For example, the one or more first isolating layers 306b and the second isolating layers 306d can include silicon oxide, the one or more first dielectric layers 306a and the second dielectric layers 306c can include silicon nitride. In some implementations, a quantity of the one or more first dielectric layers 306a in the stack 304 can be in a range between 1 to 10.

FIG. 3B illustrates a semiconductor structure 300b. The semiconductor structure 300b can be formed by filling a first dielectric material into the one or more first spaces 308 to form one or more isolation structures 310 in the stack 304. The surface of the stack 304 is also coated with the first dielectric material to form a top layer 312. In some implementations, the first dielectric material is different from a dielectric material of the one or more first isolating layers 306b and the second isolating layers 306d.

As shown in a semiconductor structure 300c of FIG. 3C, one or more second filled spaces 314 can be formed by etching the one or more first dielectric layers 306a and the one or more first isolating layers 306b along the Z direction to form one or more second spaces and filling a second dielectric material into the one or more second spaces to form one or more second filled spaces 314. The one or more second filled spaces 314 and the one or more isolating structures 310 are at different positions along the Y direction. In some implementations, the second dielectric material is different from the first dielectric material. In some implementations, as shown in FIG. 3C, a length of the second filled space 314 is equal to a length of the one or more isolation structures 310 along the Z direction. In some implementations (not shown in FIG. 3C), the length of the second filled space 314 is smaller than the length of the one or more isolation structure 310 along the Z direction. In some implementations (not shown in FIG. 3C), the one or more second filled spaces 314 are in continuous contact with one or more first dielectric layers 306a along a second horizontal direction (e.g., the X direction) perpendicular to the Z direction and the Y direction. In some implementations (not shown in FIG. 3C), the one or more second filled space 314 are in intermittent contact with one or more first dielectric layers 306a along the X direction.

FIG. 3D illustrates a semiconductor structure 300d, which can be formed by depositing a dielectric layer 316 (e.g., silicon nitride) on top of the semiconductor structure 300c.

FIG. 3E illustrates a semiconductor structure 300e. The semiconductor structure 300e can include one or more first holes that are formed by etching through the stack 304 and a portion of the one or more isolation structures 310. The semiconductor structure 300e can also include one or more second holes that are formed by etching through the stack 304 and a portion of the one or more second filled spaces 314, where the one or more second holes and the one or more first holes are separated from each other along the Y direction. The semiconductor structure 300e can also include one or more third holes that are formed by etching through the stack 304, where the one or more third holes, the one or more second holes, and the one or more first holes are separated from each other along the Y direction. One or more first channel structures 318a are formed by filling one or more filling materials into the one or more first holes. In some implementations, the one or more first channel structures 318a are partially surrounded by the corresponding one or more isolation structure 310 that is in contact with an outer layer of the one or more first channel structure 318a. One or more second channel structures 318b are formed by filling one or more filling materials into the one or more second holes. In some implementations, the one or more second channel structures 318b are partially surrounded by the corresponding one or more second filled spaces 314 that is in contact with an outer layer of the one or more second channel structure 318b. One or more third channel structures 318c are formed by filling one or more filling materials into the third holes. In some implementations, the one or more first channel structures 318a, the one or more second channel structures 318b, and the one or more third channel structures 318c can be in the shape of a cylinder or a pillar, and can include an outer layer 320a, a block layer surrounded by the outer layer, a charge trapping layer (or a storage layer) surrounded by the block layer, a tunneling layer surrounded by the charge trapping layer, a channel layer 320c surrounded by the tunneling layer, and a core filler layer 320d surrounded by the channel layer 320c. In some implementations, the channel layer 320c can include silicon, such as amorphous silicon, polysilicon, or single crystalline silicon, the tunneling layer can include silicon oxide, silicon nitride, or any combination thereof, the blocking layer can include silicon oxide, silicon nitride, high-K dielectrics, or any combination thereof, and the charge trapping layer can include silicon nitride, silicon oxynitride, silicon, or any combination thereof. In some implementations, the tunneling layer, the charge trapping layer, and the blocking layer, collectively referred to as a memory film 320b, can include ONO dielectrics (silicon Oxide-silicon Nitride-silicon Oxide).

FIG. 3F illustrates a semiconductor structure 300f, which can be formed by removing a portion of the filling one or more filling materials on the surface of the stack 304.

FIG. 3G illustrates a semiconductor structure 300g, which can be formed by depositing a semiconductor material on top of the one or more first channel structures 318a, the one or more second channel structures 318b, and the one or more third channel structures 318c to form a channel plug 320e along the Z direction. In some implementations, the channel plug 320e is formed above the core filler layer 320d and being in contact with the channel layer 320c.

FIG. 3H illustrates a semiconductor structure 300h, which can be formed by depositing a dielectric layer 322 (e.g., silicon oxide) on top of the semiconductor structure 300g.

FIG. 3I illustrates a semiconductor structure 300i, which can be formed by performing a planarization process, such as chemical mechanical polishing (CMP), to remove the excess dielectric material in the dielectric layer 322 on top of the semiconductor structure 300h.

FIG. 3J illustrates a semiconductor structure 300j. The semiconductor structure 300j can be formed by removing the one or more first dielectric layers 306a and the second dielectric layers 306c of the stack 304 and the one or more second filled spaces 314 to form a fourth space 324.

FIG. 3K illustrates a semiconductor structure 300k, which can be formed by filling a filler material into the fourth space 324 to form one or more first conductive layers 326a and second conductive layers 326b of the stack 304 and the one or more connection structures 328.

As shown in FIG. 3K, the filler material in the one or more first conductive layers 326a and second conductive layers 326b of the stack 304 includes a conductive material. In some implementations, the filler material in the connection structures 328 includes a conductive material, where the conductive material is in contact with the one or more first conductive layers 326a along the Z direction. In some implementations, the filler material of the connection structure 328 includes segments of conductive materials and dielectric materials spaced apart from each other along the Y direction, where the filler material of the connection structure 328 is in contact with the one or more first conductive layers 326a along the Z direction.

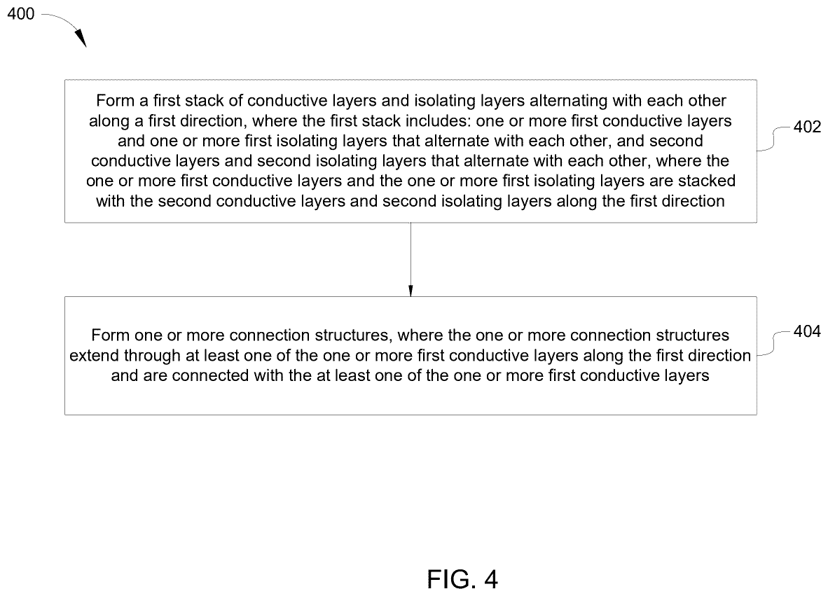

FIG. 4 illustrates a flow chart of an example process 400. The process 400 can be performed to form a semiconductor device (e.g., the semiconductor device 200 illustrated by FIGS. 2A-2B). The process 400 can be described in view of FIGS. 3A-3K. The process 400 can include one or more steps of the fabrication process of forming the semiconductor structures in FIGS. 3A-3K. It is understood that the operations shown in process 400 are not exhaustive and that other operations can be performed as well before, after, or between any of the illustrated operations. Further, some of the operations may be performed simultaneously, or in a different order than shown in FIG. 4.

At operation 402, a semiconductor structure (e.g., the semiconductor structure 300k of FIG. 3K) is formed. The semiconductor structure includes a first stack (e.g., the stack 304) of conductive layers and isolating layers alternating with each other along a first direction (e.g., the Z direction), where the first stack includes one or more first conductive layers (e.g., the one or more first conductive layers 326a) and one or more first isolating layers alternate (e.g., the one or more first isolating layers 306b) that with each other, and second conductive layers (e.g., the second conductive layers 326b) and second isolating layers (e.g., the second isolating layers 306d) that alternate with each other, where the one or more first conductive layers and the one or more first isolating layers are stacked with the second conductive layers and second isolating layers along the first direction (e.g., the Z direction).

At operation 404, one or more connection structures (e.g., the one or more connection structures 328) that extend through at least one of the one or more first conductive layers along the first direction are formed. In some implementations, the one or more connection structures are connected with the at least one of the one or more first conductive layers.

In some implementations, the forming of the first stack includes: forming a stack of dielectric layers (e.g., the one or more first dielectric layers 306a and the second dielectric layers 306c) and isolating layers (e.g., the one or more first isolating layers 306b and the second isolating layers 306d) alternating with each other along the first direction; etching one or more first dielectric layers (e.g., the one or more first dielectric layers 306a) and one or more first isolating layers (e.g., the one or more first isolating layers 306b) in the stack along the first direction and a second direction (e.g., the Y direction) in a first region to form one or more first spaces (e.g., the one or more first spaces 308), the second direction being perpendicular to the first direction; and filling a first dielectric material into the one or more first spaces to form one or more isolation structures (e.g., the one or more isolation structures 310) in the first region.

In some implementations, the first dielectric material is different from a dielectric material of the dielectric layers.

In some implementations, the process 400 includes: etching one or more first dielectric layers and one or more first isolating layers along the first direction in the first region to form one or more second spaces, where the one or more second spaces and the one or more first spaces are at different positions along a third direction perpendicular to the first direction; and filling a second dielectric material into the one or more second spaces to form one or more second filled spaces (e.g., the one or more second filled spaces 314), the second dielectric material being different from the first dielectric material.

In some implementations, the one or more second filled spaces are in continuous or intermittent contact with the one or more first dielectric layers along a third direction (e.g., the X direction) perpendicular to the first direction and the second direction.

In some implementations, a length of the one or more second filled spaces along the first direction are no greater than a length of the one or more isolation structures along the first direction.

In some implementations, the forming of the first stack further includes: forming channel structures in the first region, where the channel structures include a first channel structure (e.g., the one or more first channel structures 318a), a second channel structure (e.g., the one or more second channel structures 318b) and a third channel structure (e.g., the one or more third channel structures 318c).

In some implementations, the forming of the channel structures is after the forming of the one or more isolation structures and the forming of the one or more second filled spaces.

In some implementations, the forming of the first channel structure includes: etching through the stack of dielectric layers and isolating layers and a portion of the one or more isolation structures to form first holes; and filling one or more filling materials into the first holes to from the first channel structure, where the first channel structure partially surrounded by the corresponding isolation structure that is in contact with an outer layer of the first channel structure.

In some implementations, the forming of the second channel structure includes: etching through the stack of dielectric layers and isolating layers and a portion of the one or more second filled spaces to form second holes, where the second holes and the first holes are separated from each other along the second direction; and filling one or more filling materials into the second holes to from the second channel structure, where the second channel structure partially surrounded by the corresponding second filled spaces that is in contact with an outer layer of the first channel structure.

In some implementations, the forming of the third channel structure includes: etching through the stack of dielectric layers and isolating layers to form third holes, where the third holes, the second holes, and the first holes are separated from each other along the second direction; and filling one or more filling materials into the second holes to from the third channel structure.

In some implementations, the forming of the one or more connection structures includes: etching through the stack of dielectric layers and isolating layers along the first direction in the first region to form third spaces, where the one or more second spaces and the one or more first spaces are between two adjacent third spaces along the third direction; removing the dielectric layers of the stack and the one or more second filled spaces via the third spaces to form a fourth space (e.g., the fourth space 324); filling a conductive material into the fourth space to form the conductive layers of the first stack and the one or more connection structures; and forming gate line isolation structures in the third spaces.

In some implementations, the process 400 further includes: forming one or more contact structures extending through the stack along the first direction in a second region that is adjacent to the first region along the second direction, where one of the second conductive layers of the first stack is connected to a corresponding contact structure of the contact structures in the second region.

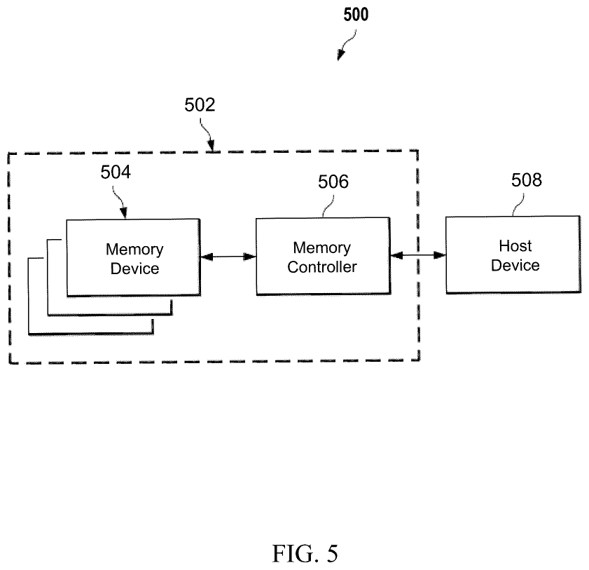

FIG. 5 illustrates a block diagram of an example system 500. The system 500 can have one or more semiconductor devices (e.g., memory devices), according to one or more implementations of the present disclosure. The system 500 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage. As shown in FIG. 5, the system 500 can include a host device 508 and a memory system 502 having one or more memory devices 504 and a memory controller 506. Host device 508 can include a processor of an electronic device, such as a central processing unit (CPU), or a system-on-chip (SoC), such as an application processor (AP). Host device 508 can be configured to send or receive data to or from the one or more memory devices 504.

A memory device 504 can be any memory device disclosed in the present disclosure, such as a memory device (e.g., a NAND Flash memory) as shown in FIGS. 2A-2B. Memory controller 506 (a.k.a., a controller circuit) is coupled to memory device 504 and host device 508. Consistent with implementations of the present disclosure, memory device 504 can include a plurality of conductive interconnections through a cover layer that are in contact with conductive pads in a conductive pad layer, and memory controller 506 can be coupled to memory device 504 through at least one of the plurality of conductive interconnections. Memory controller 506 is configured to control memory device 504. For example, memory controller 506 may be configured to operate a plurality of channel structures via word lines. Memory controller 506 can manage data stored in memory device 504 and communicate with host device 508.

In some implementations, memory controller 506 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 506 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 506 can be configured to control operations of memory device 504, such as read, erase, and program (or write) operations. Memory controller 506 can also be configured to manage various functions with respect to the data stored or to be stored in memory device 504 including, but not limited to bad-block management, garbage collection, logical-to-physical address conversion, wear leveling, etc. In some implementations, memory controller 506 is further configured to process error correction codes (ECCs) with respect to the data read from or written to memory device 504. Any other suitable functions may be performed by memory controller 506 as well, for example, formatting memory device 504.

Memory controller 506 can communicate with an external device (e.g., host device 508) according to a particular communication protocol. For example, memory controller 506 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 506 and one or more memory devices 504 can be integrated into various types of storage devices, for example, be included in the same package, such as a universal Flash storage (UFS) package or an eMMC package. That is, memory system 502 can be implemented and packaged into different types of end electronic products. In one example as shown in FIG. 5, memory controller 506 and a single memory device 504 may be integrated into a memory card 502. Memory card 502 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+ conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+−0.10%, .+−0.20%, or .+−0.30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
a first stack of conductive layers and isolating layers alternating with each other along a first direction, wherein the first stack comprises:
one or more first conductive layers and one or more first isolating layers that alternate with each other; and
second conductive layers and second isolating layers that alternate with each other,
wherein the one or more first conductive layers and the one or more first isolating layers are stacked with the second conductive layers and second isolating layers along the first direction; and
at least one connection structure extending through at least one of the one or more first conductive layers along the first direction and being connected with the at least one of the one or more first conductive layers.

2. The semiconductor device of claim 1, further comprising:
two adjacent gate line isolation structures each extending through the first stack along the first direction, the two adjacent gate line isolation structures being spaced from each other along a second direction perpendicular to the first direction and defining at least one block structure; and
channel structures between the two adjacent gate line isolation structures, each of the channel structures extending through the first stack along the first direction.

3. The semiconductor device of claim 2, further comprising:
one or more isolation structures between the two adjacent gate line isolation structures along the second direction,
wherein the one or more isolation structures separate the block structure into two or more sub-block structures, and wherein the at least one connection structure comprises a connection structure in a corresponding sub-block structure.

4. The semiconductor device of claim 3, wherein the connection structure is between one of the two adjacent gate line isolation structures and one of the one or more isolation structures adjacent to the one of the two adjacent gate line isolation structures along the second direction, or
wherein the connection structure is between two adjacent isolation structures of the one or more isolation structures along the second direction.

5. The semiconductor device of claim 3, wherein the one or more isolation structures comprise:
an isolation structure extending through the one or more first conductive layers and the one or more first isolating layers along the first direction, wherein the isolation structure is in contact with one of the second isolating layers.

6. The semiconductor device of claim 5, wherein the channel structures comprise a first channel structure that is partially surrounded by the isolation structure, and
wherein the isolation structure is in contact with an outer layer of the first channel structure.

7. The semiconductor device of claim 3, wherein the channel structures comprise a second channel structure that is partially surrounded by the connection structure, and
wherein the connection structure is in contact with an outer layer of the second channel structure.

8. The semiconductor device of claim 3, wherein the connection structure comprises a conductive material, wherein the conductive material is in contact with the one or more first conductive layers along the first direction.

9. The semiconductor device of claim 8, wherein the connection structure is continuous or intermittent along a third direction perpendicular to the first direction and the second direction.

10. The semiconductor device of claim 3, wherein the connection structure in the corresponding sub-block structure is coupled to an interconnect structure through at least one coupling-out structure.

11. The semiconductor device of claim 1, further comprising:
gate line structures each extending through the first stack along the first direction, two adjacent gate line slits being spaced from each other along the second direction perpendicular to the first direction and defining a block;
one or more gate line isolation structures between the two adjacent gate line slits, the one or more gate line isolation structures separating the block into two or more block structures; and
one or more isolation structures between two adjacent gate line isolation structures or between a gate line structure and an adjacent gate line isolation structure, the one or more isolation structure separating a block structure into two or more sub-block structures.

12. A method, comprising:
forming a first stack comprising one or more first conductive layers and one or more first isolating layers that alternate with each other along a first direction, and second conductive layers and second isolating layers that alternate with each other along the first direction, wherein the one or more first conductive layers and the one or more first isolating layers are stacked with the second conductive layers and second isolating layers along the first direction; and
forming one or more connection structures, wherein the one or more connection structures extend through at least one of the one or more first conductive layers along the first direction and is connected with the at least one of the one or more first conductive layers.

13. The method of claim 12, wherein the forming of the first stack comprises:
forming a stack of dielectric layers and isolating layers alternating with each other along the first direction;
etching one or more first dielectric layers and one or more first isolating layers in the stack along the first direction and a second direction in a first region to form one or more first spaces, the second direction being perpendicular to the first direction; and
filling a first dielectric material into the one or more first spaces to form one or more isolation structures in the first region.

14. The method of claim 13, wherein the method comprises:
etching one or more first dielectric layers and one or more first isolating layers along the first direction in the first region to form one or more second spaces, wherein the one or more second spaces and the one or more first spaces are at different positions along a third direction perpendicular to the first direction; and
filling a second dielectric material into the one or more second spaces to form one or more second filled spaces, the second dielectric material being different from the first dielectric material.

15. The method of claim 14, wherein the one or more second filled spaces are in continuous or intermittent contact with the one or more first dielectric layers along a third direction perpendicular to the first direction and the second direction.

16. The method of claim 14, wherein the forming of the first stack further comprises:
forming channel structures in the first region, wherein the channel structures comprise a first channel structure, second channel structure and a third channel structure.

17. The method of claim 16, wherein the forming of the channel structures is after the forming of the one or more isolation structures and the forming of the one or more second filled spaces.

18. The method of claim 17, wherein the forming of the first channel structure comprising:
etching through the stack of dielectric layers and isolating layers and a portion of the one or more isolation structures to form first holes; and
filling one or more filling materials into the first holes to from the first channel structure,
wherein the first channel structure partially surrounded by the corresponding isolation structure that is in contact with an outer layer of the first channel structure; and
wherein the forming of the second channel structure comprising:
etching through the stack of dielectric layers and isolating layers and a portion of the one or more second filled spaces to form second holes, wherein the second holes and the first holes are separated from each other along the second direction; and
filling one or more filling materials into the second holes to from the second channel structure, wherein the second channel structure partially surrounded by the corresponding second filled spaces that is in contact with an outer layer of the first channel structure.

19. The method of claim 18, wherein the forming of the third channel structure comprising:
etching through the stack of dielectric layers and isolating layers to form third holes,
wherein the third holes, the second holes, and the first holes are separated from each other along the second direction; and
filling one or more filling materials into the third holes to from the third channel structure.

20. A semiconductor device, comprising:
a first stack comprising conductive layers and isolating layers alternating with each other along a first direction;
channel structures extending through the first stack; and
at least one connection structure extending through at least one conductive layer and at least one isolating layer of the first stack along the first direction and being connected with the at least one conductive layer, wherein the at least one conductive layer and the at least one isolating layer locate at a side of the first stack along the first direction.
